(19) United States
(12) Patent Application Publication
(10) Pub. No.: US 2026/0269807 A1
(43) Pub. Date: Sep. 10, 2026

(54) ACOUSTIC WAVE RESONATOR, ACOUSTIC WAVE FILTER, AND MULTIPLEXER

(71) Applicant: Murata Manufacturing Co., Ltd., Nagaokakyo-shi (JP)

(72) Inventors: Toshiki TABEI, Nagaokakyo-shi (JP); Tomohisa KOMURA, Nagaokakyo-shi (JP)

(21) Appl. No.: 19/541,778

(22) Filed: Feb. 17, 2026

(30) Foreign Application Priority Data
Mar. 4, 2025 (JP) 2025-033972

(51) Int. Cl. H03H 9/13; H03H 9/70

(52) U.S. Cl. CPC H03H 9/133; H03H 9/703

(57) ABSTRACT

An acoustic wave resonator includes first and second IDT electrodes on a piezoelectric substrate, and first to fourth reflection electrodes. The first IDT electrode includes first and second electrode fingers and first and second busbar electrodes. The second IDT electrode includes third and fourth electrode fingers and third and fourth busbar electrodes. The first and second reflection electrodes and the third and fourth reflection electrodes respectively sandwich the first and second IDT electrodes. Electrode fingers located outermost in the first IDT electrode, and electrode fingers located outermost in the second IDT electrode are respectively connected to the first to fourth reflection electrodes.

### CROSS REFERENCE TO RELATED APPLICATIONS

This application claims the benefit of priority to Japanese Patent Application No. 2025-033972 filed on Mar. 4, 2025. The entire contents of this application are hereby incorporated herein by reference.

### BACKGROUND OF THE INVENTION

### 1. Field of the Invention

The present invention relates to acoustic wave resonators, acoustic wave filters, and multiplexers.

### 2. Description of the Related Art

Japanese Unexamined Patent Application Publication No. 2016-82570 discloses an acoustic wave device including a first interdigital transducer (IDT) electrode and a second IDT electrode connected in series. It is disclosed that by setting a width of a busbar common to the first IDT electrode and the second IDT electrode to twice a wavelength or less and not providing a dummy electrode in the common busbar, compatibility between improvement in electric power handling capability and miniaturization can be achieved.

While miniaturization of acoustic wave filters is demanded, there is a problem that gaps between electrode fingers of IDT electrodes and reflection electrodes become narrow, and a risk of failure due to electrostatic discharge damage increases.

### SUMMARY OF THE INVENTION

Example embodiments of the present invention provide small-sized acoustic wave resonators, acoustic wave filters, and multiplexers in each of which electrostatic discharge damage is reduced or prevented.

An acoustic wave resonator according to an example embodiment of the present invention includes a piezoelectric substrate, a first IDT electrode and a second IDT electrode disposed on the piezoelectric substrate, and a first reflection electrode, a second reflection electrode, a third reflection electrode, and a fourth reflection electrode. The first IDT electrode includes a plurality of first electrode fingers and a plurality of second electrode fingers parallel or substantially parallel to each other, and a first busbar electrode and a second busbar electrode. The first busbar electrode connects one end of each of the plurality of first electrode fingers to each other. The second busbar electrode connects one end of each of the plurality of second electrode fingers to each other. Respective other ends of the plurality of first electrode fingers face the second busbar electrode. Respective other ends of the plurality of second electrode fingers face the first busbar electrode. The second IDT electrode includes a plurality of third electrode fingers and a plurality of fourth electrode fingers parallel or substantially parallel to each other, and the second busbar electrode and a third busbar electrode. The second busbar electrode connects one end of each of the plurality of third electrode fingers to each other. The third busbar electrode connects one end of each of the plurality of fourth electrode fingers to each other. Respective other ends of the plurality of third electrode fingers face the third busbar electrode. Respective other ends of the plurality of fourth electrode fingers face the second busbar electrode. The first reflection electrode and the second reflection electrode sandwich the first IDT electrode in a first direction intersecting an extending direction of the plurality of first electrode fingers. The third reflection electrode and the fourth reflection electrode sandwich the second IDT electrode in a second direction intersecting an extending direction of the plurality of third electrode fingers. At least one of two electrode fingers located outermost in the first direction among the plurality of first electrode fingers and the plurality of second electrode fingers is connected to at least one of the first reflection electrode and the second reflection electrode. At least one of two electrode fingers located outermost in the second direction among the plurality of third electrode fingers and the plurality of fourth electrode fingers is connected to at least one of the third reflection electrode and the fourth reflection electrode.

An acoustic wave filter according to an example embodiment of the present invention includes a acoustic wave resonator according to an example embodiment of the present invention.

A multiplexer according to an example embodiment of the present invention includes a common terminal, an acoustic wave filter according to an example embodiment of the present invention connected to the common terminal, and a first filter connected to the common terminal.

According to example embodiments of the present invention, small-sized acoustic wave resonators, acoustic wave filters, and multiplexers are provided, in each of which electrostatic discharge damage is reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B is a plan view and a sectional view of an acoustic wave resonator according to Example 1 of an example embodiment of the present invention.

FIG. 2 is a diagram explaining parasitic capacitance of the acoustic wave resonator according to Example 1 of an example embodiment of the present invention.

FIG. 3A is a sectional view of an acoustic wave resonator according to Modification 1 of an example embodiment of the present invention.

FIG. 3B is a sectional view of an acoustic wave resonator according to Modification 2 of an example embodiment of the present invention.

FIG. 4 is a plan view of an acoustic wave resonator according to Example 2 of an example embodiment of the present invention.

FIG. 5 is a diagram explaining parasitic capacitance of the acoustic wave resonator according to Example 2 of an example embodiment of the present invention.

FIG. 6 is a plan view of an acoustic wave resonator according to Example 3 of an example embodiment of the present invention.

FIG. 7 is a diagram explaining parasitic capacitance of the acoustic wave resonator according to Example 3 of an example embodiment of the present invention.

FIG. 8 is a circuit configuration diagram of a multiplexer according to an example embodiment of the present invention.

### DETAILED DESCRIPTION OF THE EXAMPLE EMBODIMENTS

Example embodiments of the present invention will be described in detail with reference to the drawings. The example embodiments described below all show comprehensive or specific examples. Numerical values, shapes, materials, components, arrangement and connection configurations of components, and the like shown in the following example embodiments are examples, and are not intended to limit the present invention.

Each drawing is a schematic diagram in which emphasis, omission, or adjustment of ratios has been provided as appropriate to show example embodiments of the present invention, is not necessarily strictly illustrated, and may differ from actual shapes, positional relationships, and ratios. In each drawing, the same or substantially the same configurations are denoted by the same reference numerals, and overlapping descriptions may be omitted or simplified.

In the circuit configurations described in the present disclosure, “connected between A and B” means connected to both A and B between A and B. A case of being indirectly connected to A and B is also included.

Further, in the component arrangement described in the present disclosure, “component A is arranged in series in path B” means that both a signal input end and a signal output end of the component A are connected within the path B. The path B is defined by a wiring line, an electrode, or a terminal, for example.

Further, terms indicating relationships between elements such as “parallel” and “vertical,” terms indicating shapes of elements such as “rectangular,” and numerical ranges do not represent only strict meanings, but mean to include a substantially equivalent range, for example, an error of about several percent.

Further, in the present disclosure, a “terminal” means a point where a conductor within an element ends. When impedance of a conductor between elements is sufficiently low, a terminal is interpreted as not only a single point but also an arbitrary point on the conductor between the elements or the entire conductor.

Further, in the present disclosure, a passband of a filter is a portion of a frequency spectrum transmitted by the filter, and is defined as a frequency band between two frequencies that are about 3 dB larger than a minimum value of power insertion loss.

Further, in the present disclosure, a resonant frequency and an anti-resonant frequency are derived by, for example, bringing RF probes into contact with two input/output electrodes of an acoustic wave resonator in a state where the acoustic wave resonator is not connected to other circuit elements, and measuring reflection characteristics (impedance characteristics) with a network analyzer or the like, for example.

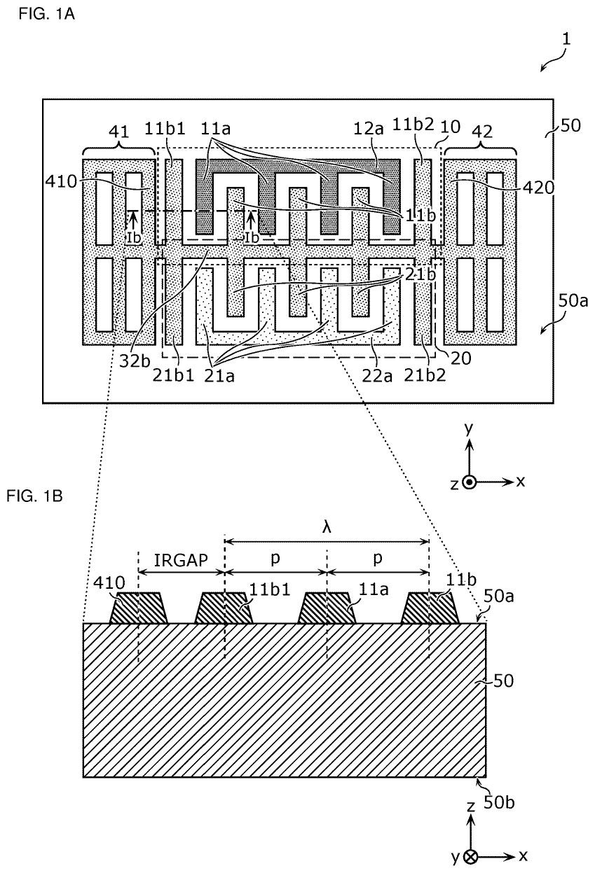

FIG. 1A includes a plan view and FIG. 1B a sectional view of an acoustic wave resonator 1 according to Example 1 of an example embodiment of the present invention. FIG. 1A is a view of a main surface 50a of a piezoelectric substrate 50 viewed in plan from a z-axis positive side. FIG. 1B is a sectional view taken along line Ib-Ib in FIG. 1A viewed from a y-axis negative side.

As shown in FIGS. 1A and 1B, the acoustic wave resonator 1 includes a piezoelectric substrate 50, IDT electrodes 10 and 20, and reflection electrodes 41 and 42. The acoustic wave resonator 1 shown in FIGS. 1A and 1B is for explaining a typical structure of the acoustic wave resonator 1 according to Example 1, and the number and length of electrode fingers of the IDT electrodes 10 and 20 and the reflection electrodes 41 and 42 are not limited thereto.

The piezoelectric substrate 50 is an example of a piezoelectric substrate, includes main surfaces 50a and 50b facing each other, and is a piezoelectric single crystal substrate including a single layer of a piezoelectric body. The piezoelectric substrate 50 is, for example, a single crystal substrate made of lithium tantalate. The piezoelectric substrate 50 may also be a single crystal substrate made of lithium niobate, quartz crystal, or potassium nitride, for example.

The IDT electrode 10 is an example of a first IDT electrode and is disposed on the main surface 50a. As shown in FIG. 1A, the IDT electrode 10 includes a plurality of electrode fingers 11a and a plurality of electrode fingers 11b, and busbar electrodes 12a and 32b. The plurality of electrode fingers 11a are an example of a plurality of first electrode fingers and are disposed parallel to each other. The plurality of electrode fingers 11b are an example of a plurality of second electrode fingers and are disposed parallel to each other. The plurality of electrode fingers 11a and the plurality of electrode fingers 11b are disposed parallel so as to be interdigitated with each other.

The busbar electrode 12a is an example of a first busbar electrode and is configured to connect one end of each of the plurality of electrode fingers 11a to each other. The busbar electrode 12a extends in a first direction (x-axis direction in FIGS. 1A and 1B) intersecting an extending direction of the plurality of electrode fingers 11a (y-axis direction in FIGS. 1A and 1B).

The busbar electrode 32b is an example of a second busbar electrode and is configured to connect one end of each of the plurality of electrode fingers 11b to each other. The busbar electrode 32b extends in a first direction (x-axis direction in FIGS. 1A and 1B) intersecting an extending direction of the plurality of electrode fingers 11b (y-axis direction in FIGS. 1A and 1B). The busbar electrode 12a and the busbar electrode 32b are disposed facing each other with the plurality of electrode fingers 11a and the plurality of electrode fingers 11b interposed therebetween. Respective other ends of the plurality of electrode fingers 11a face the busbar electrode 32b, and respective other ends of the plurality of electrode fingers 11b face the busbar electrode 12a.

The IDT electrode 20 is an example of a second IDT electrode and is disposed on the main surface 50a. As shown in FIG. 1A, the IDT electrode 20 includes a plurality of electrode fingers 21a and a plurality of electrode fingers 21b, and busbar electrodes 22a and 32b. The plurality of electrode fingers 21b are an example of a plurality of third electrode fingers and are disposed parallel to each other. The plurality of electrode fingers 21a are an example of a plurality of fourth electrode fingers and are disposed parallel to each other. The plurality of electrode fingers 21a and the plurality of electrode fingers 21b are disposed parallel so as to be interdigitated with each other.

The busbar electrode 32b is an example of a second busbar electrode and is configured to connect one end of each of the plurality of electrode fingers 21b to each other. The busbar electrode 32b extends in a first direction (x-axis direction in FIGS. 1A and 1B) intersecting an extending direction of the plurality of electrode fingers 21b (y-axis direction in FIGS. 1A and 1B).

The busbar electrode 22a is an example of a third busbar electrode and is configured to connect one end of each of the plurality of electrode fingers 21a to each other. The busbar electrode 22a extends in a first direction (x-axis direction in FIGS. 1A and 1B) intersecting an extending direction of the plurality of electrode fingers 21a (y-axis direction in FIGS. 1A and 1B). The busbar electrode 32b and the busbar electrode 22a are disposed facing each other with the plurality of electrode fingers 21a and the plurality of electrode fingers 21b interposed therebetween. Respective other ends of the plurality of electrode fingers 21b face the busbar electrode 22a, and respective other ends of the plurality of electrode fingers 21a face the busbar electrode 32b.

The reflection electrode 41 is an example of a first reflection electrode and a third reflection electrode, and includes a plurality of reflection electrode fingers 410 extending in the y-axis direction. The reflection electrode 42 is an example of a second reflection electrode and a fourth reflection electrode, and includes a plurality of reflection electrode fingers 420 extending in the y-axis direction. The reflection electrodes 41 and 42 sandwich the IDT electrodes 10 and 20 in a first direction (x-axis direction) intersecting extending directions of the plurality of electrode fingers 11a and the plurality of electrode fingers 21b.

The reflection electrode 41 includes a first reflection electrode disposed in the x-axis negative direction of the IDT electrode 10 and a third reflection electrode disposed in the x-axis negative direction of the IDT electrode 20. That is, the first reflection electrode and the third reflection electrode are connected to define one reflection electrode 41.

The reflection electrode 42 includes a second reflection electrode disposed in the x-axis positive direction of the IDT electrode 10 and a fourth reflection electrode disposed in the x-axis positive direction of the IDT electrode 20. That is, the second reflection electrode and the fourth reflection electrode are connected to define one reflection electrode 42.

Each of the IDT electrodes 10 and 20 and the reflection electrodes 41 and 42 has, for example, a laminated structure of titanium (Ti), aluminum (Al), and titanium (Ti). The IDT electrodes 10 and 20 and the reflection electrodes 41 and 42 are not limited to the above laminated structure, and, for example, a material including at least one of copper (Cu), gold (Au), silver (Ag), molybdenum (Mo), tungsten (W), titanium (Ti), nickel (Ni), or chromium (Cr), or an alloy or laminated film including several of these metals may be used.

A dielectric film may be provided so as to cover the IDT electrodes 10 and 20 and the reflection electrodes 41 and 42. The dielectric film is a layer intended to protect the IDT electrodes 10 and 20 and the reflection electrodes 41 and 42 from the external environment, adjust frequency temperature characteristics, and improve moisture resistance, and mainly includes silicon dioxide (SiO₂), for example.

Further, a dielectric film or an insulating film may be disposed between the IDT electrodes 10 and 20 and the reflection electrodes 41 and 42, and the main surface 50a.

With the above configuration, the IDT electrode 10 and the piezoelectric substrate 50 define a first split resonator, the IDT electrode 20 and the piezoelectric substrate 50 define a second split resonator, and the first split resonator and the second split resonator are connected in series. That is, each of the first split resonator and the second split resonator is a series split resonator. According to this, it becomes possible to improve electric power handling capability and resistance to electrostatic discharge damage compared to a case where the acoustic wave resonator 1 includes one IDT electrode and the piezoelectric substrate 50.

The busbar electrode 32b is connected to the reflection electrodes 41 and 42, and electrode fingers 11b1 and 11b2 located outermost in the first direction (x-axis direction) among the plurality of electrode fingers 11a and the plurality of electrode fingers 11b are connected to the reflection electrodes 41 and 42. Further, electrode fingers 21b1 and 21b2 located outermost in the second direction (x-axis direction) among the plurality of electrode fingers 21a and the plurality of electrode fingers 21b are connected to the reflection electrodes 41 and 42.

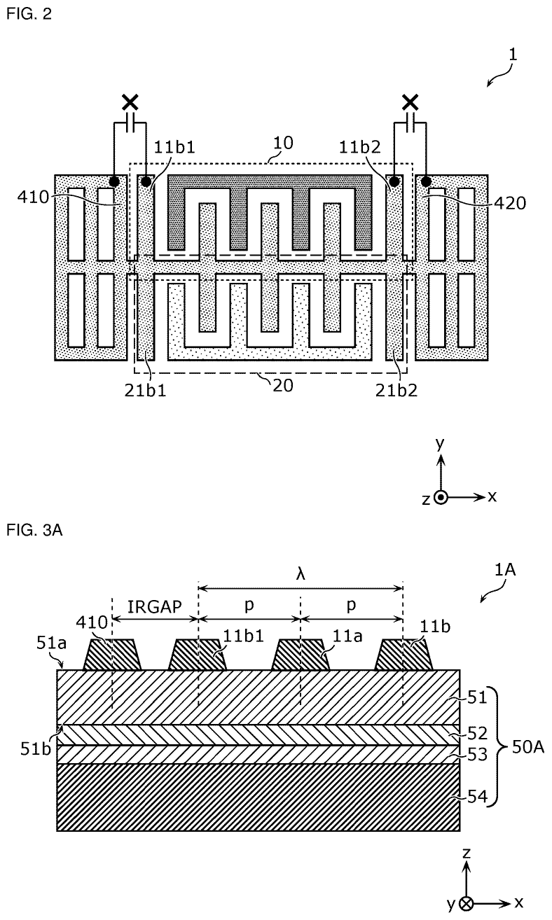

FIG. 2 is a diagram explaining parasitic capacitance of the acoustic wave resonator 1 according to Example 1. Generally, in the design of an IDT electrode, a pitch between an electrode finger of the IDT electrode and a reflection electrode finger of a reflection electrode (hereinafter referred to as IRGAP) is often smaller than an electrode finger pitch of the IDT electrode. Therefore, a parasitic capacitance of an IRGAP portion occurring between the electrode finger of the IDT electrode and the reflection electrode finger of the reflection electrode becomes larger than a capacitance occurring between the electrode fingers of the IDT electrode. Thus, in the IDT electrode, a probability of an occurrence of electrostatic discharge damage in the IRGAP portion increases.

In contrast, in the acoustic wave resonator 1 according to the present example embodiment, the electrode fingers 11b1 and 11b2 located outermost in the x-axis direction among the plurality of electrode fingers 11a and the plurality of electrode fingers 11b are at the same potential as the reflection electrodes 41 and 42. Further, the electrode fingers 21b1 and 21b2 located outermost in the x-axis direction among the plurality of electrode fingers 21a and the plurality of electrode fingers 21b are at the same potential as the reflection electrodes 41 and 42. According to this configuration, parasitic capacitance occurring in the IRGAP portion between the electrode finger 11b1 and the reflection electrode 41, and parasitic capacitance occurring in the IRGAP portion between the electrode finger 11b2 and the reflection electrode 42 are extremely small. Further, parasitic capacitance occurring in the IRGAP portion between the electrode finger 21b1 and the reflection electrode 41, and parasitic capacitance occurring in the IRGAP portion between the electrode finger 21b2 and the reflection electrode 42 are extremely small. Therefore, since electrostatic discharge damage in the IDT electrodes 10 and 20 can be reduced or prevented even if the IRGAP is reduced, the small-sized acoustic wave resonator 1 in which electrostatic discharge damage is reduced or prevented can be provided.

Further, since the parasitic capacitance occurring in the IRGAP portion becomes connected in parallel between the input and output of the acoustic wave resonator 1, it reduces a fractional bandwidth of the acoustic wave resonator 1 (a value obtained by dividing a difference frequency between the anti-resonant frequency and the resonant frequency by an average value of the anti-resonant frequency and the resonant frequency), but in the present example embodiment, since the parasitic capacitance is extremely small, a reduction in the fractional bandwidth can be reduced or prevented.

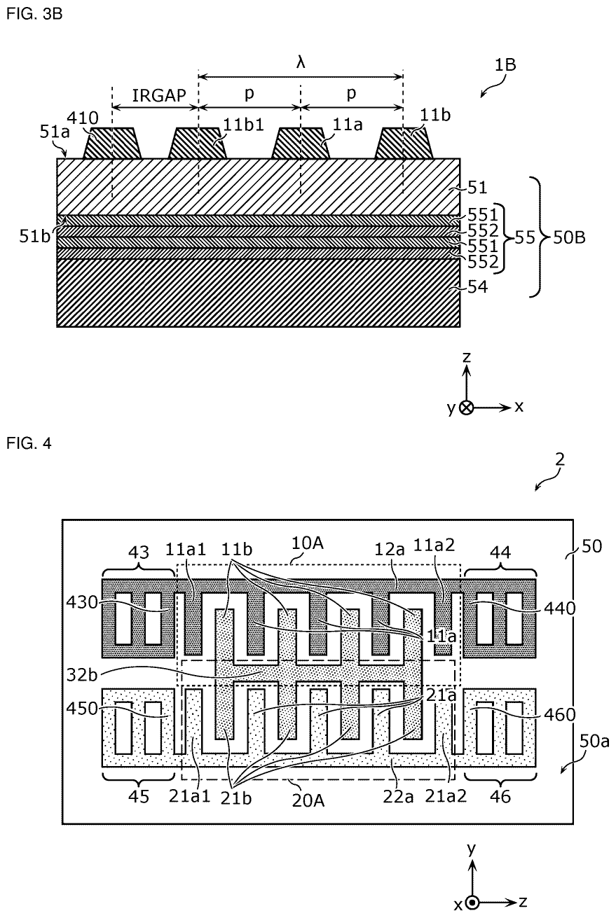

The piezoelectric substrate included in the acoustic wave resonator according to the present invention is not limited to the piezoelectric substrate described above. FIG. 3A is a sectional view of an acoustic wave resonator 1A according to Modification 1 of an example embodiment of the present invention. The acoustic wave resonator 1A according to the present modification includes a piezoelectric substrate 50A, IDT electrodes 10 and 20, and reflection electrodes 41 and 42. The acoustic wave resonator 1A according to the present modification differs only in the configuration of the piezoelectric substrate compared to the acoustic wave resonator 1 according to Example 1. Therefore, in the following, regarding the acoustic wave resonator 1A according to the present modification, description of the IDT electrodes 10 and 20, which have the same or substantially the same configuration as the acoustic wave resonator 1 according to Example 1, will be omitted, and description will focus on the piezoelectric substrate 50A, which has a different configuration.

As shown in FIG. 3A, the piezoelectric substrate 50A includes a piezoelectric layer 51, a low acoustic velocity layer 52, a high acoustic velocity layer 53, and a support substrate 54.

The piezoelectric layer 51 includes main surfaces 51a and 51b facing each other, and is disposed above (z-axis positive direction) the low acoustic velocity layer 52, the high acoustic velocity layer 53, and the support substrate 54. For the piezoelectric layer 51, for example, lithium tantalate or a material mainly including lithium tantalate can be used. A material such as, for example, lithium niobate, quartz crystal, or potassium nitride can also be used for the piezoelectric layer 51.

The low acoustic velocity layer 52 is disposed between the piezoelectric layer 51 and the high acoustic velocity layer 53, and includes, for example, at least one of silicon oxide and silicon oxynitride. A bulk wave acoustic velocity of the low acoustic velocity layer 52 is lower than bulk wave acoustic velocities of the piezoelectric layer 51 and the support substrate 54.

For the low acoustic velocity layer 52, a dielectric such as, for example, silicon oxide, silicon oxynitride, glass, lithium oxide, tantalum pentoxide, or a compound obtained by adding fluorine, carbon, or boron to silicon oxide, or a material mainly including the above materials may be used.

The high acoustic velocity layer 53 is disposed between the low acoustic velocity layer 52 and the support substrate 54, and includes, for example, silicon nitride. A bulk wave acoustic velocity of the high acoustic velocity layer 53 is higher than the bulk wave acoustic velocity of the low acoustic velocity layer 52.

For the high acoustic velocity layer 53, for example, silicon nitride, silicon oxynitride, amorphous silicon, polysilicon, aluminum oxide or aluminum nitride, or a material mainly including the above materials may be used. Furthermore, for the high acoustic velocity layer 53, for example, silicon, aluminum oxide, silicon carbide, silicon oxynitride, sapphire, lithium tantalate, lithium niobate, quartz crystal, alumina, zirconia, cordierite, mullite, steatite, forsterite, magnesia, diamond-like carbon (DLC) film or diamond, or a material mainly including the above materials may be used.

At least one of the low acoustic velocity layer 52 and the high acoustic velocity layer 53 need not be included in the piezoelectric substrate 50A.

The support substrate 54 is disposed on the main surface 51b side of the piezoelectric layer 51, and is a substrate that supports the IDT electrodes 10 and 20, the reflection electrodes 41 and 42, the piezoelectric layer 51, the low acoustic velocity layer 52, and the high acoustic velocity layer 53.

For the support substrate 54, for example, a piezoelectric body such as aluminum nitride, aluminum oxide, lithium niobate, or quartz crystal, a ceramic such as sapphire, magnesia, silicon nitride, silicon carbide, zirconia, cordierite, mullite, steatite, or forsterite, a dielectric such as diamond or glass, a semiconductor such as silicon or gallium nitride, or a resin, or a material mainly including the above materials can be used.

According to the above laminated structure of the piezoelectric substrate 50A, it becomes possible to significantly increase the Q value at the resonant frequency and the anti-Resonant frequency compared to a structure including a piezoelectric substrate as a single layer. That is, since the acoustic wave resonator 1A having a high Q value can be provided, it becomes possible to provide an acoustic wave filter with small insertion loss using the acoustic wave resonator 1A.

FIG. 3B is a sectional view of an acoustic wave resonator 1B according to Modification 2 on an example embodiment of the present invention. The acoustic wave resonator 1B according to the present modification includes a piezoelectric substrate 50B, IDT electrodes 10 and 20, and reflection electrodes 41 and 42. The acoustic wave resonator 1B according to the present modification differs only in the configuration of the piezoelectric substrate compared to the acoustic wave resonator 1 according to Example 1. Therefore, in the following, regarding the acoustic wave resonator 1B according to the present modification, description of the IDT electrodes 10 and 20, which have the same or substantially the same configuration as the acoustic wave resonator 1 according to Example 1, will be omitted, and description will focus on the piezoelectric substrate 50B, which has a different configuration.

As shown in FIG. 3B, the piezoelectric substrate 50B includes a piezoelectric layer 51, an energy confinement layer 55, and a support substrate 54.

The piezoelectric layer 51 includes main surfaces 51a and 51b facing each other, and is disposed above (z-axis positive direction) the energy confinement layer 55 and the support substrate 54.

The energy confinement layer 55 is disposed between the support substrate 54 and the piezoelectric layer 51, includes one layer or a plurality of layers, and a bulk wave acoustic velocity propagating through at least one layer thereof is larger than a bulk wave acoustic velocity propagating near the piezoelectric layer 51. In the energy confinement layer 55, low acoustic impedance layers 551 and high acoustic impedance layers 552 are alternately laminated from the piezoelectric layer 51 toward the support substrate 54. The high acoustic impedance layer 552 has relatively higher acoustic impedance compared to the low acoustic impedance layer 551. According to the arrangement of the energy confinement layer 55, an acoustic wave propagating through the piezoelectric layer 51 is efficiently reflected by the energy confinement layer 55, and leakage to the support substrate 54 side can be reduced or prevented.

The support substrate 54 is disposed on the main surface 51b side of the piezoelectric layer 51, and is a substrate that supports the IDT electrodes 10 and 20, the reflection electrodes 41 and 42, the piezoelectric layer 51, and the energy confinement layer 55.

In the acoustic wave resonator 1B shown in FIG. 3B, an air gap may be provided instead of the energy confinement layer 55. According to this, the acoustic wave resonator 1B defines and functions as a laterally excited bulk acoustic resonator (XBAR).

FIG. 4 is a plan view of an acoustic wave resonator 2 according to Example 2 of an example embodiment of the present invention. FIG. 4 is a view of a main surface 50a of a piezoelectric substrate 50 viewed in plan from a z-axis positive side. Note that the sectional structure of the acoustic wave resonator 2 according to the present example is the same or substantially the same as the sectional structure of the acoustic wave resonator 1 according to Example 1 shown in FIG. 1B.

As shown in FIG. 4, the acoustic wave resonator 2 includes a piezoelectric substrate 50, IDT electrodes 10A and 20A, and reflection electrodes 43, 44, 45, and 46. The acoustic wave resonator 2 shown in FIG. 4 is for explaining a typical structure of the acoustic wave resonator 2 according to Example 2, and the number and length of electrode fingers of the IDT electrodes 10A and 20A and the reflection electrodes 43 to 46 are not limited thereto.

The acoustic wave resonator 2 according to the present example differs in the configuration of the IDT electrodes 10A and 20A and the reflection electrodes 43 to 46 compared to the acoustic wave resonator 1 according to Example 1. Therefore, in the following, regarding the acoustic wave resonator 2 according to the present example embodiment, description of the piezoelectric substrate 50, which has the same or substantially the same configuration as the acoustic wave resonator 1 according to Example 1, will be omitted, and description will focus on the IDT electrodes 10A and 20A and the reflection electrodes 43 to 46, which have different configurations.

The IDT electrode 10A is an example of a first IDT electrode and is disposed on the main surface 50a. As shown in FIG. 4, the IDT electrode 10A includes a plurality of electrode fingers 11a and a plurality of electrode fingers 11b, and busbar electrodes 12a and 32b. The plurality of electrode fingers 11a are an example of a plurality of first electrode fingers and are disposed parallel to each other. The plurality of electrode fingers 11b are an example of a plurality of second electrode fingers and are disposed parallel to each other. The plurality of electrode fingers 11a and the plurality of electrode fingers 11b are disposed parallel so as to be interdigitated with each other.

The busbar electrode 12a is an example of a first busbar electrode and is configured to connect one end of each of the plurality of electrode fingers 11a to each other. The busbar electrode 12a extends in a first direction (x-axis direction in FIG. 4) intersecting an extending direction of the plurality of electrode fingers 11a (y-axis direction in FIG. 4).

The busbar electrode 32b is an example of a second busbar electrode and is configured to connect one end of each of the plurality of electrode fingers 11b to each other. The busbar electrode 32b extends in a first direction (x-axis direction in FIG. 4) intersecting an extending direction of the plurality of electrode fingers 11b (y-axis direction in FIG. 4). The busbar electrode 12a and the busbar electrode 32b are disposed facing each other with the plurality of electrode fingers 11a and the plurality of electrode fingers 11b interposed therebetween. Respective other ends of the plurality of electrode fingers 11a face the busbar electrode 32b, and respective other ends of the plurality of electrode fingers 11b face the busbar electrode 12a.

The IDT electrode 20A is an example of a second IDT electrode and is disposed on the main surface 50a. As shown in FIG. 4, the IDT electrode 20A includes a plurality of electrode fingers 21a and a plurality of electrode fingers 21b, and busbar electrodes 22a and 32b. The plurality of electrode fingers 21b are an example of a plurality of third electrode fingers and are disposed parallel to each other. The plurality of electrode fingers 21a are an example of a plurality of fourth electrode fingers and are disposed parallel to each other. The plurality of electrode fingers 21a and the plurality of electrode fingers 21b are disposed parallel so as to be interdigitated with each other.

The busbar electrode 32b is an example of a second busbar electrode and is configured to connect one end of each of the plurality of electrode fingers 21b to each other. The busbar electrode 32b extends in a first direction (x-axis direction in FIG. 4) intersecting an extending direction of the plurality of electrode fingers 21b (y-axis direction in FIG. 4).

The busbar electrode 22a is an example of a third busbar electrode and is configured to connect one end of each of the plurality of electrode fingers 21a to each other. The busbar electrode 22a extends in a first direction (x-axis direction in FIG. 4) intersecting an extending direction of the plurality of electrode fingers 21a (y-axis direction in FIG. 4). The busbar electrode 32b and the busbar electrode 22a are disposed facing each other with the plurality of electrode fingers 21a and the plurality of electrode fingers 21b interposed therebetween. Respective other ends of the plurality of electrode fingers 21b face the busbar electrode 22a, and respective other ends of the plurality of electrode fingers 21a face the busbar electrode 32b.

The reflection electrode 43 is an example of a first reflection electrode and includes a plurality of reflection electrode fingers 430 extending in the y-axis direction. The reflection electrode 44 is an example of a second reflection electrode and includes a plurality of reflection electrode fingers 440 extending in the y-axis direction. The reflection electrodes 43 and 44 sandwich the IDT electrode 10A in a first direction (x-axis direction) intersecting an extending direction of the plurality of electrode fingers 11a.

The reflection electrode 45 is an example of a third reflection electrode and includes a plurality of reflection electrode fingers 450 extending in the y-axis direction. The reflection electrode 46 is an example of a fourth reflection electrode and includes a plurality of reflection electrode fingers 460 extending in the y-axis direction. The reflection electrodes 45 and 46 sandwich the IDT electrode 20A in a first direction (x-axis direction) intersecting an extending direction of the plurality of electrode fingers 21a.

Each of the IDT electrodes 10A and 20A and the reflection electrodes 43 to 46 has, for example, a laminated structure of titanium (Ti), aluminum (Al), and titanium (Ti). The IDT electrodes 10A and 20A and the reflection electrodes 43 to 46 are not limited to the above laminated structure, and, for example, a material including at least one of copper (Cu), gold (Au), silver (Ag), molybdenum (Mo), tungsten (W), titanium (Ti), nickel (Ni), or chromium (Cr), or an alloy or laminated film including several of these metals may be used.

A dielectric film may be provided so as to cover the IDT electrodes 10A and 20A and the reflection electrodes 43 to 46. The dielectric film is a layer intended to protect the IDT electrodes 10A and 20A and the reflection electrodes 43 to 46 from the external environment, adjust frequency temperature characteristics, and improve moisture resistance, and mainly include silicon dioxide (SiO₂), for example.

Further, a dielectric film or an insulating film may be disposed between the IDT electrodes 10A and 20A and the reflection electrodes 43 to 46, and the main surface 50a.

With the above configuration, the IDT electrode 10A and the piezoelectric substrate 50 define a first split resonator, the IDT electrode 20A and the piezoelectric substrate 50 define a second split resonator, and the first split resonator and the second split resonator are connected in series. That is, each of the first split resonator and the second split resonator is a series split resonator. According to this, it becomes possible to improve electric power handling capability and resistance to electrostatic discharge damage compared to a case where the acoustic wave resonator 2 includes one IDT electrode and the piezoelectric substrate 50.

Further, the reflection electrode 43 and the reflection electrode 45 are provided separately, and the reflection electrode 44 and the reflection electrode 46 are provided separately. Thus, capacitance can be generated between the reflection electrode 43 and the reflection electrode 45. Since this capacitance becomes connected in parallel between the input and output of the acoustic wave resonator 2, for example, by adjusting a distance between the reflection electrode 43 and the reflection electrode 45 and a distance between the reflection electrode 44 and the reflection electrode 46, a capacitance value of the capacitance can be adjusted. By adjusting the capacitance value of the capacitance, it becomes possible to adjust the fractional bandwidth of the acoustic wave resonator 2.

The busbar electrode 12a is connected to the reflection electrodes 43 and 44, and the busbar electrode 22a is connected to the reflection electrodes 45 and 46. Electrode fingers 11a1 and 11a2 located outermost in the first direction (x-axis direction) among the plurality of electrode fingers 11a and the plurality of electrode fingers 11b are connected to the reflection electrodes 43 and 44. Further, electrode fingers 21a1 and 21a2 located outermost in the second direction (x-axis direction) among the plurality of electrode fingers 21a and the plurality of electrode fingers 21b are connected to the reflection electrodes 45 and 46.

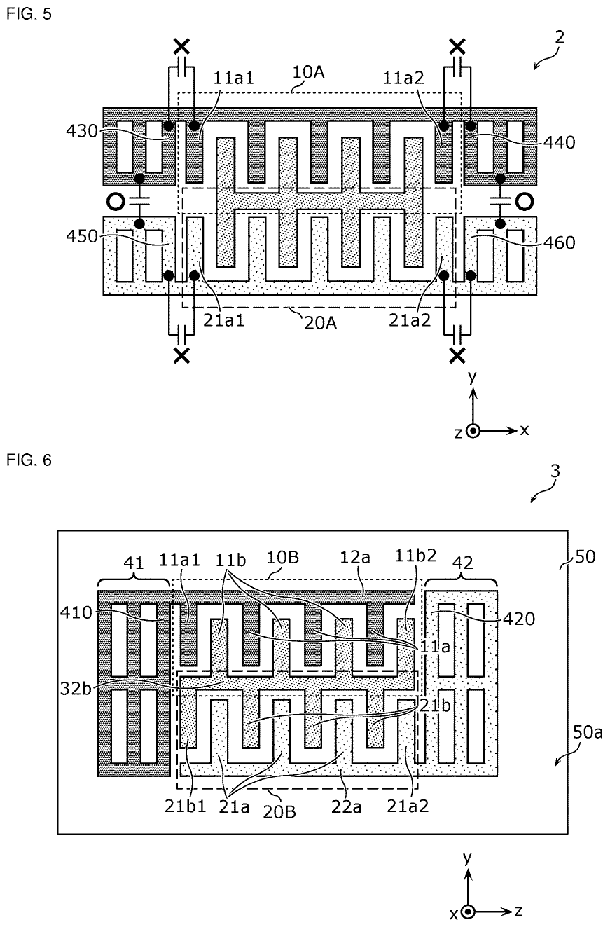

FIG. 5 is a diagram explaining parasitic capacitance of the acoustic wave resonator 2 according to Example 2 of an example embodiment of the present invention. In the acoustic wave resonator 2 according to the present example, the electrode fingers 11a1 and 11a2 located outermost in the x-axis direction among the plurality of electrode fingers 11a and the plurality of electrode fingers 11b are at the same potential as the reflection electrodes 43 and 44. Further, the electrode fingers 21a1 and 21a2 located outermost in the x-axis direction among the plurality of electrode fingers 21a and the plurality of electrode fingers 21b are at the same potential as the reflection electrodes 45 and 46. According to this, parasitic capacitance occurring in the IRGAP portion between the electrode finger 11a1 and the reflection electrode 43, and parasitic capacitance occurring in the IRGAP portion between the electrode finger 11a2 and the reflection electrode 44 are extremely small. Further, parasitic capacitance occurring in the IRGAP portion between the electrode finger 21a1 and the reflection electrode 45, and parasitic capacitance occurring in the IRGAP portion between the electrode finger 21a2 and the reflection electrode 46 are extremely small. Therefore, since electrostatic discharge damage in the IDT electrodes 10A and 20A can be reduced or prevented even if the IRGAP is reduced, the small-sized acoustic wave resonator 2 in which electrostatic discharge damage is reduced or prevented can be provided.

Further, since the parasitic capacitance occurring in the IRGAP portion becomes connected in parallel between the input and output of the acoustic wave resonator 2, it reduces the fractional bandwidth of the acoustic wave resonator 2, but in the present example, since the parasitic capacitance is extremely small, a reduction in the fractional bandwidth can be reduced or prevented.

FIG. 6 is a plan view of an acoustic wave resonator 3 according to Example 3 of an example embodiment of the present invention. FIG. 6 is a view of a main surface 50a of a piezoelectric substrate 50 viewed in plan from a z-axis positive side. The sectional structure of the acoustic wave resonator 3 according to the present example is the same or substantially the same as the sectional structure of the acoustic wave resonator 1 according to Example 1 shown in FIG. 1B.

As shown in FIG. 6, the acoustic wave resonator 3 includes a piezoelectric substrate 50, IDT electrodes 10B and 20B, and reflection electrodes 41 and 42. The acoustic wave resonator 3 shown in FIG. 6 is for explaining a typical structure of the acoustic wave resonator 3 according to Example 3, and the number and length of electrode fingers of the IDT electrodes 10B and 20B and the reflection electrodes 41 and 42 are not limited thereto.

The acoustic wave resonator 3 according to the present example differs in the configuration of the IDT electrodes 10B and 20B and the reflection electrodes 41 and 42 compared to the acoustic wave resonator 1 according to Example 1. Therefore, in the following, regarding the acoustic wave resonator 3 according to the present example, description of the piezoelectric substrate 50, which has the same or substantially the same configuration as the acoustic wave resonator 1 according to Example 1, will be omitted, and description will focus on the IDT electrodes 10B and 20B and the reflection electrodes 41 and 42, which have different configurations.

The IDT electrode 10B is an example of a first IDT electrode and is disposed on the main surface 50a. As shown in FIG. 6, the IDT electrode 10B includes a plurality of electrode fingers 11a and a plurality of electrode fingers 11b, and busbar electrodes 12a and 32b. The plurality of electrode fingers 11a are an example of a plurality of first electrode fingers and are disposed parallel to each other. The plurality of electrode fingers 11b are an example of a plurality of second electrode fingers and are disposed parallel to each other. The plurality of electrode fingers 11a and the plurality of electrode fingers 11b are disposed parallel so as to be interdigitated with each other.

The busbar electrode 12a is an example of a first busbar electrode and is configured to connect one end of each of the plurality of electrode fingers 11a to each other. The busbar electrode 12a extends in a first direction (x-axis direction in FIG. 6) intersecting an extending direction of the plurality of electrode fingers 11a (y-axis direction in FIG. 6).

The busbar electrode 32b is an example of a second busbar electrode and is configured to connect one end of each of the plurality of electrode fingers 11b to each other. The busbar electrode 32b extends in a first direction (x-axis direction in FIG. 6) intersecting an extending direction of the plurality of electrode fingers 11b (y-axis direction in FIG. 6). The busbar electrode 12a and the busbar electrode 32b are disposed facing each other with the plurality of electrode fingers 11a and the plurality of electrode fingers 11b interposed therebetween. Respective other ends of the plurality of electrode fingers 11a face the busbar electrode 32b, and respective other ends of the plurality of electrode fingers 11b face the busbar electrode 12a.

The IDT electrode 20B is an example of a second IDT electrode and is disposed on the main surface 50a. As shown in FIG. 6, the IDT electrode 20B includes a plurality of electrode fingers 21a and a plurality of electrode fingers 21b, and busbar electrodes 22a and 32b. The plurality of electrode fingers 21b are an example of a plurality of third electrode fingers and are disposed parallel to each other. The plurality of electrode fingers 21a are an example of a plurality of fourth electrode fingers and are disposed parallel to each other. The plurality of electrode fingers 21a and the plurality of electrode fingers 21b are disposed parallel so as to be interdigitated with each other.

The busbar electrode 32b is an example of a second busbar electrode and is configured to connect one end of each of the plurality of electrode fingers 21b to each other. The busbar electrode 32b extends in a first direction (x-axis direction in FIG. 6) intersecting an extending direction of the plurality of electrode fingers 21b (y-axis direction in FIG. 6).

The busbar electrode 22a is an example of a third busbar electrode and is configured to connect one end of each of the plurality of electrode fingers 21a to each other. The busbar electrode 22a extends in a first direction (x-axis direction in FIG. 6) intersecting an extending direction of the plurality of electrode fingers 21a (y-axis direction in FIG. 6). The busbar electrode 32b and the busbar electrode 22a are disposed facing each other with the plurality of electrode fingers 21a and the plurality of electrode fingers 21b interposed therebetween. Respective other ends of the plurality of electrode fingers 21b face the busbar electrode 22a, and respective other ends of the plurality of electrode fingers 21a face the busbar electrode 32b.

The reflection electrode 41 is an example of a first reflection electrode and a third reflection electrode, and includes a plurality of reflection electrode fingers 410 extending in the y-axis direction. The reflection electrode 42 is an example of a second reflection electrode and a fourth reflection electrode, and includes a plurality of reflection electrode fingers 420 extending in the y-axis direction. The reflection electrodes 41 and 42 sandwich the IDT electrodes 10B and 20B in a first direction (x-axis direction) intersecting extending directions of the plurality of electrode fingers 11a and the plurality of electrode fingers 21b.

The reflection electrode 41 includes a first reflection electrode disposed in the x-axis negative direction of the IDT electrode 10B and a third reflection electrode disposed in the x-axis negative direction of the IDT electrode 20B. That is, the first reflection electrode and the third reflection electrode are connected to define one reflection electrode 41.

The reflection electrode 42 includes a second reflection electrode disposed in the x-axis positive direction of the IDT electrode 10B and a fourth reflection electrode disposed in the x-axis positive direction of the IDT electrode 20B. That is, the second reflection electrode and the fourth reflection electrode are connected to define one reflection electrode 42.

Each of the IDT electrodes 10B and 20B and the reflection electrodes 41 and 42 has, for example, a laminated structure of titanium (Ti), aluminum (Al), and titanium (Ti). The IDT electrodes 10B and 20B and the reflection electrodes 41 and 42 are not limited to the above laminated structure, and, for example, a material including at least one of copper (Cu), gold (Au), silver (Ag), molybdenum (Mo), tungsten (W), titanium (Ti), nickel (Ni), or chromium (Cr), or an alloy or laminated film including several of these metals may be used.

A dielectric film may be provided so as to cover the IDT electrodes 10B and 20B and the reflection electrodes 41 and 42. The dielectric film is a layer intended to protect the IDT electrodes 10B and 20B and the reflection electrodes 41 and 42 from the external environment, adjust frequency temperature characteristics, and improve moisture resistance, and mainly includes silicon dioxide (SiO₂), for example.

Further, a dielectric film or an insulating film may be disposed between the IDT electrodes 10B and 20B and the reflection electrodes 41 and 42, and the main surface 50a.

With the above configuration, the IDT electrode 10B and the piezoelectric substrate 50 define a first split resonator, the IDT electrode 20B and the piezoelectric substrate 50 define a second split resonator, and the first split resonator and the second split resonator are connected in series. That is, each of the first split resonator and the second split resonator is a series split resonator. According to this configuration, it becomes possible to improve electric power handling capability and resistance to electrostatic discharge damage compared to a case where the acoustic wave resonator 3 includes one IDT electrode and the piezoelectric substrate 50.

The busbar electrode 12a is connected to the reflection electrode 41, and the busbar electrode 22a is connected to the reflection electrode 42. An electrode finger 11a1 located outermost in the first direction (x-axis direction) among the plurality of electrode fingers 11a and the plurality of electrode fingers 11b is connected to the reflection electrode 41. Further, an electrode finger 21a2 located outermost in the second direction (x-axis direction) among the plurality of electrode fingers 21a and the plurality of electrode fingers 21b is connected to the reflection electrode 42.

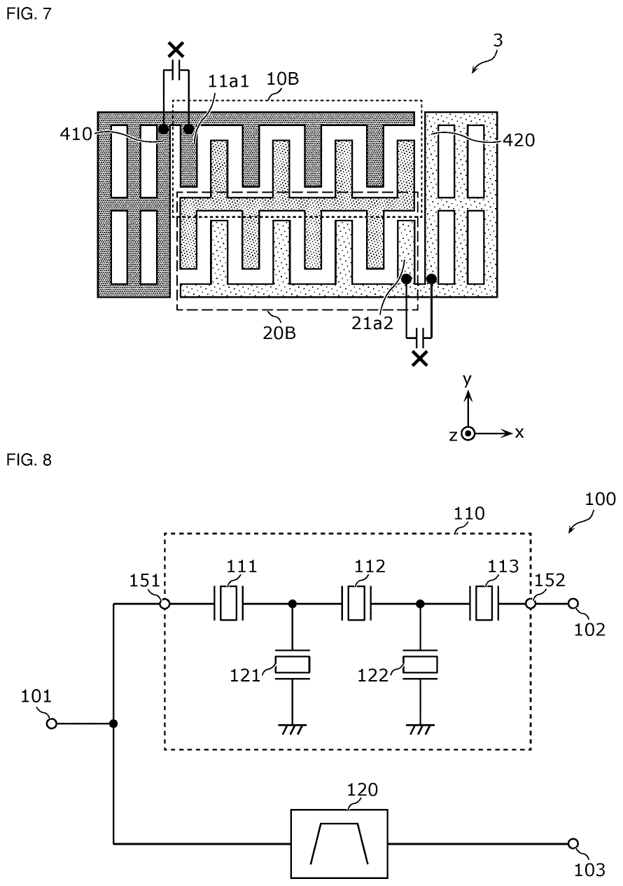

FIG. 7 is a diagram explaining parasitic capacitance of the acoustic wave resonator 3 according to Example 3 of an example embodiment of the present invention. In the acoustic wave resonator 3 according to the present example, the electrode finger 11a1 located outermost in the x-axis direction among the plurality of electrode fingers 11a and the plurality of electrode fingers 11b is at the same potential as the reflection electrode 41. Further, the electrode finger 21a2 located outermost in the x-axis direction among the plurality of electrode fingers 21a and the plurality of electrode fingers 21b is at the same potential as the reflection electrode 42. According to this, parasitic capacitance occurring in the IRGAP portion between the electrode finger 11a1 and the reflection electrode 41, and parasitic capacitance occurring in the IRGAP portion between the electrode finger 21a2 and the reflection electrode 42 are extremely small. Further, an electrode finger 11b2 located outermost in the x-axis direction among the plurality of electrode fingers 11a and the plurality of electrode fingers 11b, and an electrode finger 21b1 located outermost in the x-axis direction among the plurality of electrode fingers 21a and the plurality of electrode fingers 21b are at the same potential as the busbar electrode 32b and are at a floating potential. For this reason, a potential difference of the IRGAP portion between the electrode finger 11b2 and the reflection electrode 42, and a potential difference of the IRGAP portion between the electrode finger 21b1 and the reflection electrode 41 are small. Therefore, since electrostatic discharge damage in the IDT electrodes 10B and 20B can be reduced or prevented even if the IRGAP is reduced, the small-sized acoustic wave resonator 3 in which electrostatic discharge damage is reduced or prevented can be provided.

Further, since the parasitic capacitance occurring in the IRGAP portion becomes connected in parallel between the input and output of the acoustic wave resonator 3, it reduces the fractional bandwidth of the acoustic wave resonator 3, but in the present example, since the parasitic capacitance is extremely small, a reduction in the fractional bandwidth can be reduced or prevented.

Next, configurations of an acoustic wave filter 110 and a multiplexer 100 according to example embodiments of the present invention including the acoustic wave resonators according to Examples 1 to 3 will be described.

FIG. 8 is a circuit configuration diagram of the multiplexer 100 in the present example embodiment. As shown in FIG. 8, the multiplexer 100 includes a common terminal 101, input/output terminals 102 and 103, the acoustic wave filter 110, and a filter 120. The common terminal 101 is connected to, for example, an antenna.

The acoustic wave filter 110 includes input/output terminals 151 and 152, series arm resonators 111, 112 and 113, and parallel arm resonators 121 and 122. The input/output terminal 151 is connected to the common terminal 101.

Each of the series arm resonators 111 to 113 is disposed in series in a path connecting the input/output terminal 151 (first input/output terminal) and the input/output terminal 152 (second input/output terminal). Each of the parallel arm resonators 121 and 122 is connected between the path and a ground. With the above configuration, the acoustic wave filter 110 defines a ladder band pass filter.

The filter 120 is an example of a first filter, and is connected to the common terminal 101.

Here, in the acoustic wave filter 110, at least one of the series arm resonators 111 to 113 and the parallel arm resonators 121 and 122 is the acoustic wave resonator 1 according to Example 1. According to this, since at least one of resonators of the acoustic wave filter 110 is miniaturized and electrostatic discharge damage is reduced or prevented, the small-sized acoustic wave filter 110 in which electrostatic discharge damage is reduced or prevented can be provided.

Among the series arm resonators 111 to 113 and the parallel arm resonators 121 and 122, at least one of the series arm resonators 111 and 113 and the parallel arm resonators 121 and 122 is the acoustic wave resonator 1 according to Example 1. A resonator directly connected to at least one of the input/output terminals 151 and 152 and a ground terminal is susceptible to a surge (ESD) due to static electricity from an external circuit. According to this, since electrostatic discharge damage of the resonator susceptible to receiving ESD from the external circuit can be reduced or prevented, electrostatic discharge damage of the acoustic wave filter 110 can be effectively reduced or prevented.

At least one of the series arm resonators 111 to 113 and the parallel arm resonators 121 and 122 may be the acoustic wave resonator 3 according to Example 3. According to this, since at least one of resonators of the acoustic wave filter 110 is miniaturized and electrostatic discharge damage is reduced or prevented, the small-sized acoustic wave filter 110 in which electrostatic discharge damage is reduced or prevented can be provided. Further, since the acoustic wave filter 110 of the multiplexer 100 is miniaturized and electrostatic discharge damage is reduced or prevented, the small-sized multiplexer 100 in which electrostatic discharge damage is reduced or prevented can be provided.

Among the series arm resonators 111 to 113 and the parallel arm resonators 121 and 122, at least one of the series arm resonators 111 and 113 and the parallel arm resonators 121 and 122 may be the acoustic wave resonator 3 according to Example 3. According to this, since electrostatic discharge damage of the resonator susceptible to receiving ESD from the external circuit can be reduced or prevented, electrostatic discharge damage of the acoustic wave filter 110 can be effectively reduced or prevented.

Among the series arm resonators 111 to 113 and the parallel arm resonators 121 and 122, at least one of the series arm resonators 111 to 113 may be the acoustic wave resonator 2 according to Example 2. Thus, at least one of the series arm resonators 111 to 113 can reduce a fractional bandwidth by capacitance generated between the reflection electrodes 43 and 45 and capacitance generated between the reflection electrodes 44 and 46. Therefore, bandpass characteristics at a high frequency end of a passband of the acoustic wave filter 110 can be steepened.

Further, among the series arm resonators 111 to 113 and the parallel arm resonators 121 and 122, at least one of the parallel arm resonators 121 and 122 may be the acoustic wave resonator 2 according to Example 2. Thus, at least one of the parallel arm resonators 121 and 122 can reduce a fractional bandwidth by capacitance generated between the reflection electrodes 43 and 45 and capacitance generated between the reflection electrodes 44 and 46. Therefore, bandpass characteristics at a low frequency end of a passband of the acoustic wave filter 110 can be steepened.

Further, a first series arm resonator which is one of the series arm resonators 111 to 113, and a first parallel arm resonator which is one of the parallel arm resonators 121 and 122, may each be the acoustic wave resonator 2 according to Example 2.

Here, an average gap of a gap between the reflection electrodes 43 and 45 and a gap between the reflection electrodes 44 and 46 of the first series arm resonator is larger than an average gap of a gap between the reflection electrodes 43 and 45 and a gap between the reflection electrodes 44 and 46 of the first parallel arm resonator. According to this, steepness of bandpass characteristics at the high frequency end of the passband of the acoustic wave filter 110 can be increased relative to steepness of bandpass characteristics at the low frequency end of the passband.

Alternatively, an average gap of a gap between the reflection electrodes 43 and 45 and a gap between the reflection electrodes 44 and 46 of the first series arm resonator is smaller than an average gap of a gap between the reflection electrodes 43 and 45 and a gap between the reflection electrodes 44 and 46 of the first parallel arm resonator. According to this, steepness of bandpass characteristics at the low frequency end of the passband of the acoustic wave filter 110 can be increased relative to steepness of bandpass characteristics at the high frequency end of the passband.

In the acoustic wave filter 110, the number of series arm resonators only needs to be one or more, and the number of parallel arm resonators only needs to be one or more. Further, the acoustic wave filter 110 need not be a ladder filter, and may be, for example, a longitudinally coupled filter having a configuration in which a plurality of acoustic wave resonators are juxtaposed.

As described above, the acoustic wave resonator 1 according to Example 1, the acoustic wave resonator 2 according to Example 2, and the acoustic wave resonator 3 according to Example 3 include a piezoelectric substrate (piezoelectric substrate 50, piezoelectric substrate 50A or 50B), a first IDT electrode (10, 10A or 10B) and a second IDT electrode (20, 20A or 20B) disposed on the piezoelectric substrate, and a first reflection electrode (41 or 43), a second reflection electrode (42 or 44), a third reflection electrode (41 or 45), and a fourth reflection electrode (42 or 46), the first IDT electrode includes a plurality of electrode fingers 11a and a plurality of electrode fingers 11b disposed parallel to each other, and busbar electrodes 12a and 32b, the busbar electrode 12a is configured to connect one end of each of the plurality of electrode fingers 11a to each other, the busbar electrode 32b is configured to connect one end of each of the plurality of electrode fingers 11b to each other, respective other ends of the plurality of electrode fingers 11a face the busbar electrode 32b, respective other ends of the plurality of electrode fingers 11b face the busbar electrode 12a, the second IDT electrode includes a plurality of electrode fingers 21b and a plurality of electrode fingers 21a disposed parallel to each other, and busbar electrodes 32b and 22a, the busbar electrode 32b is configured to connect one end of each of the plurality of electrode fingers 21b to each other, the busbar electrode 22a is configured to connect one end of each of the plurality of electrode fingers 21a to each other, respective other ends of the plurality of electrode fingers 21b face the busbar electrode 22a, respective other ends of the plurality of electrode fingers 21a face the busbar electrode 32b, the first reflection electrode and the second reflection electrode sandwich the first IDT electrode in a first direction intersecting an extending direction of the plurality of electrode fingers 11a, the third reflection electrode and the fourth reflection electrode sandwich the second IDT electrode in a second direction intersecting an extending direction of the plurality of electrode fingers 21b, at least one of two electrode fingers located outermost in the first direction among the plurality of electrode fingers 11a and the plurality of electrode fingers 11b is connected to at least one of the first reflection electrode and the second reflection electrode, and at least one of two electrode fingers located outermost in the second direction among the plurality of electrode fingers 21a and the plurality of electrode fingers 21b is connected to at least one of the third reflection electrode and the fourth reflection electrode.

According to this, at least one of the two electrode fingers located outermost in the first direction among the plurality of electrode fingers 11a and the plurality of electrode fingers 11b has the same potential as at least one of the first reflection electrode and the second reflection electrode. Further, at least one of the two electrode fingers located outermost in the second direction among the plurality of electrode fingers 21a and the plurality of electrode fingers 21b has the same potential as at least one of the third reflection electrode and the fourth reflection electrode. According to this, parasitic capacitance occurring in an IRGAP portion becomes extremely small. Therefore, since electrostatic discharge damage in the first IDT electrode and the second IDT electrode can be reduced or prevented even if the IRGAP is reduced, a small-sized acoustic wave resonator in which electrostatic discharge damage is reduced or prevented can be provided. Further, since the parasitic capacitance can be reduced to be extremely small, a reduction in the fractional bandwidth of the acoustic wave resonator can be reduced or prevented.

Also, for example, in the acoustic wave resonator 1 according to Example 1, the busbar electrode 32b is connected to the reflection electrodes 41 and 42, electrode fingers 11b1 and 11b2 located outermost in the first direction among the plurality of electrode fingers 11a and the plurality of electrode fingers 11b are connected to the reflection electrodes 41 and 42, and electrode fingers 21b1 and 21b2 located outermost in the second direction among the plurality of electrode fingers 21b and the plurality of electrode fingers 21a are connected to the reflection electrodes 41 and 42.

According to this, the electrode fingers 11b1 and 11b2 have the same potential as the reflection electrodes 41 and 42. Further, the electrode fingers 21b1 and 21b2 have the same potential as the reflection electrodes 41 and 42. Therefore, since electrostatic discharge damage in the IDT electrodes 10 and 20 can be reduced or prevented even if the IRGAP is reduced, the small-sized acoustic wave resonator 1 in which electrostatic discharge damage is reduced or prevented can be provided. Further, since the parasitic capacitance can be reduced to be extremely small, a reduction in the fractional bandwidth of the acoustic wave resonator 1 can be reduced or prevented.

Also, for example, in the acoustic wave resonator 3 according to Example 3, the busbar electrode 12 a is connected to the reflection electrode 41, the busbar electrode 22a is connected to the reflection electrode 42, an electrode finger 11a1 located outermost in the first direction among the plurality of electrode fingers 11a and the plurality of electrode fingers 11b is connected to the reflection electrode 41, and an electrode finger 21a2 located outermost in the second direction among the plurality of electrode fingers 21b and the plurality of electrode fingers 21a is connected to the reflection electrode 42.

According to this, parasitic capacitance occurring in an IRGAP portion between the electrode finger 11a1 and the reflection electrode 41 and parasitic capacitance occurring in an IRGAP portion between the electrode finger 21a2 and the reflection electrode 42 are extremely small. Further, the electrode fingers 11b2 and 21b1 have the same potential as the busbar electrode 32b and are at a floating potential. For this reason, a potential difference of an IRGAP portion between the electrode finger 11b2 and the reflection electrode 42, and a potential difference of an IRGAP portion between the electrode finger 21b1 and the reflection electrode 41 are small. Therefore, since electrostatic discharge damage in the IDT electrodes 10B and 20B can be reduced or prevented even if the IRGAP is reduced, the small-sized acoustic wave resonator 3 in which electrostatic discharge damage is reduced or prevented can be provided. Further, since the parasitic capacitance can be reduced to be extremely small, a reduction in the fractional bandwidth of the acoustic wave resonator 3 can be reduced or prevented.

Also, for example, in the acoustic wave resonator 2 according to Example 2, the busbar electrode 12a is connected to the reflection electrodes 43 and 44, the busbar electrode 22a is connected to the reflection electrodes 45 and 46, electrode fingers 11a1 and 11a2 located outermost in the first direction among the plurality of electrode fingers 11a and the plurality of electrode fingers 11b are connected to the reflection electrodes 43 and 44, and electrode fingers 21a1 and 21a2 located outermost in the second direction among the plurality of electrode fingers 21b and the plurality of electrode fingers 21a are connected to the reflection electrodes 45 and 46.

According to this, the electrode fingers 11a1 and 11a2 have the same potential as the reflection electrodes 43 and 44. Further, the electrode fingers 21a1 and 21a2 have the same potential as the reflection electrodes 45 and 46. Thus, parasitic capacitance occurring in an IRGAP portion is extremely small. Therefore, since electrostatic discharge damage in the IDT electrodes 10A and 20A can be reduced or prevented even if the IRGAP is reduced, the small-sized acoustic wave resonator 2 in which electrostatic discharge damage is reduced or prevented can be provided. Further, since the parasitic capacitance can be reduced to be extremely small, a reduction in the fractional bandwidth of the acoustic wave resonator 2 can be reduced or prevented.

Further, the acoustic wave filter 110 according to the above-described example embodiment includes at least one of the acoustic wave resonators 1 to 3.

According to this, since at least one of resonators of the acoustic wave filter 110 is miniaturized and electrostatic discharge damage is reduced or prevented, the small-sized acoustic wave filter 110 in which electrostatic discharge damage is reduced or prevented can be provided.

Also, for example, the acoustic wave filter 110 further includes input/output terminals 151 and 152 and a ground terminal, and at least one of the acoustic wave resonators 1 and 3 is directly connected to at least one of the input/output terminals 151 and 152 and the ground terminal.

According to this, since electrostatic discharge damage of the resonator susceptible to receiving ESD from the external circuit can be reduced or prevented, electrostatic discharge damage of the acoustic wave filter 110 can be effectively reduced or prevented.

Also, for example, the acoustic wave filter 110 includes input/output terminals 151 and 152, series arm resonators 111 to 113 disposed in series in a path connecting the input/output terminals 151 and 152, and parallel arm resonators 121 and 122 connected between the path and a ground, and at least one of the series arm resonators 111 to 113 is the acoustic wave resonator 2.

According to this, at least one of the series arm resonators 111 to 113 can reduce a fractional bandwidth by capacitance generated between the reflection electrodes 43 and 45, and capacitance generated between the reflection electrodes 44 and 46. Therefore, bandpass characteristics at a high frequency end of a passband of the acoustic wave filter 110 can be steepened.

Also, for example, in the acoustic wave filter 110, the acoustic wave resonator 2 is directly connected to at least one of the input/output terminals 151 and 152.

According to this, since electrostatic discharge damage of the resonator susceptible to receiving ESD from the external circuit can be reduced or prevented, electrostatic discharge damage of the acoustic wave filter 110 can be effectively reduced or prevented.

Also, for example, the acoustic wave filter 110 includes input/output terminals 151 and 152, series arm resonators 111 to 113 disposed in series in a path connecting the input/output terminals 151 and 152, and parallel arm resonators 121 and 122 connected between the path and a ground, and at least one of the parallel arm resonators 121 and 122 is the acoustic wave resonator 2.

According to this, at least one of the parallel arm resonators 121 and 122 can reduce a fractional bandwidth by capacitance generated between the reflection electrodes 43 and 45, and capacitance generated between the reflection electrodes 44 and 46. Therefore, bandpass characteristics at a low frequency end of a passband of the acoustic wave filter 110 can be steepened.

Also, for example, in the acoustic wave filter 110, the acoustic wave resonator 2 is directly connected to at least one of the input/output terminals 151 and 152 and a ground terminal.

According to this, since electrostatic discharge damage of the resonator susceptible to receiving ESD from the external circuit can be reduced or prevented, electrostatic discharge damage of the acoustic wave filter 110 can be effectively reduced or prevented.

Also, for example, the acoustic wave filter 110 includes input/output terminals 151 and 152, series arm resonators 111 to 113 disposed in series in a path connecting the input/output terminals 151 and 152, and parallel arm resonators 121 and 122 connected between the path and a ground, a first series arm resonator among the series arm resonators 111 to 113 and a first parallel arm resonator among the parallel arm resonators 121 and 122 are each the acoustic wave resonator 2, and an average gap of a gap between the reflection electrode 43 and the reflection electrode 45 and a gap between the reflection electrode 44 and the reflection electrode 46 of the first series arm resonator is larger than an average gap of a gap between the reflection electrode 43 and the reflection electrode 45 and a gap between the reflection electrode 44 and the reflection electrode 46 of the first parallel arm resonator.

According to this, steepness of bandpass characteristics at a high frequency end of a passband of the acoustic wave filter 110 can be increased compared to steepness of bandpass characteristics at a low frequency end of the passband.

Also, for example, the acoustic wave filter 110 includes input/output terminals 151 and 152, series arm resonators 111 to 113 disposed in series in a path connecting the input/output terminals 151 and 152, and parallel arm resonators 121 and 122 connected between the path and a ground, a first series arm resonator among the series arm resonators 111 to 113 and a first parallel arm resonator among the parallel arm resonators 121 and 122 are each the acoustic wave resonator 2, and an average gap of a gap between the reflection electrode 43 and the reflection electrode 45 and a gap between the reflection electrode 44 and the reflection electrode 46 of the first series arm resonator is smaller than an average gap of a gap between the reflection electrode 43 and the reflection electrode 45 and a gap between the reflection electrode 44 and the reflection electrode 46 of the first parallel arm resonator.

According to this, steepness of bandpass characteristics at a low frequency end of a passband of the acoustic wave filter 110 can be increased compared to steepness of bandpass characteristics at a high frequency end of the passband.

Further, the multiplexer 100 according to the present example embodiment includes the common terminal 101, the acoustic wave filter 110 connected to the common terminal 101, and the filter 120 connected to the common terminal 101.

According to this, in the multiplexer 100, the same advantageous effects as the acoustic wave filter 110 can be achieved.

Example embodiments of the present invention have been described above regarding the acoustic wave resonators, the acoustic wave filters, and the multiplexers. However, the acoustic wave resonators, the acoustic wave filters, and the multiplexers of the present invention are not limited to the above-described example embodiments. Other example embodiments obtained by combining arbitrary components in the above example embodiments, variations obtained by applying various modifications that those skilled in the art can conceive to the above example embodiments without departing from the scope and gist of the present invention, and various apparatuses incorporating the acoustic wave resonators, the acoustic wave filters, and the multiplexers according to the above-described example embodiments are also included in the present invention.

Example embodiments of the present invention can be widely used in communication equipment such as, for example, cellular phones as an acoustic wave filter and a multiplexer with low loss and high attenuation applicable to multi-band frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave resonator comprising:
a piezoelectric substrate;
a first interdigital transducer (IDT) electrode and a second IDT electrode on the piezoelectric substrate; and
a first reflection electrode, a second reflection electrode, a third reflection electrode, and a fourth reflection electrode; wherein
the first IDT electrode includes:
a plurality of first electrode fingers and a plurality of second electrode fingers parallel to each other; and
a first busbar electrode and a second busbar electrode;
the first busbar electrode connects one end of each of the plurality of first electrode fingers to each other;
the second busbar electrode connects one end of each of the plurality of second electrode fingers to each other;
respective other ends of the plurality of first electrode fingers face the second busbar electrode;
respective other ends of the plurality of second electrode fingers face the first busbar electrode;
the second IDT electrode includes:
a plurality of third electrode fingers and a plurality of fourth electrode fingers parallel to each other; and
the second busbar electrode and a third busbar electrode;
the second busbar electrode connects one end of each of the plurality of third electrode fingers to each other;
the third busbar electrode connects one end of each of the plurality of fourth electrode fingers to each other;
respective other ends of the plurality of third electrode fingers face the third busbar electrode;
respective other ends of the plurality of fourth electrode fingers face the second busbar electrode;
the first reflection electrode and the second reflection electrode sandwich the first IDT electrode in a first direction intersecting an extending direction of the plurality of first electrode fingers;
the third reflection electrode and the fourth reflection electrode sandwich the second IDT electrode in a second direction intersecting an extending direction of the plurality of third electrode fingers;
at least one of two electrode fingers located outermost in the first direction among the plurality of first electrode fingers and the plurality of second electrode fingers is connected to at least one of the first reflection electrode and the second reflection electrode; and
at least one of two electrode fingers located outermost in the second direction among the plurality of third electrode fingers and the plurality of fourth electrode fingers is connected to at least one of the third reflection electrode and the fourth reflection electrode.

2. The acoustic wave resonator according to claim 1, wherein
the first reflection electrode and the third reflection electrode are connected to each other;
the second reflection electrode and the fourth reflection electrode are connected to each other;
the second busbar electrode is connected to the first reflection electrode, the second reflection electrode, the third reflection electrode, and the fourth reflection electrode;
a second electrode finger located outermost in the first direction among the plurality of first electrode fingers and the plurality of second electrode fingers is connected to the first reflection electrode and the second reflection electrode; and
a third electrode finger located outermost in the second direction among the plurality of third electrode fingers and the plurality of fourth electrode fingers is connected to the third reflection electrode and the fourth reflection electrode.

3. The acoustic wave resonator according to claim 1, wherein
the first reflection electrode and the third reflection electrode are connected to each other;
the second reflection electrode and the fourth reflection electrode are connected to each other;
the first busbar electrode is connected to the first reflection electrode;
the third busbar electrode is connected to the fourth reflection electrode;
a first electrode finger located outermost in the first direction among the plurality of first electrode fingers and the plurality of second electrode fingers is connected to the first reflection electrode; and
a fourth electrode finger located outermost in the second direction among the plurality of third electrode fingers and the plurality of fourth electrode fingers is connected to the fourth reflection electrode.

4. An acoustic wave filter comprising the acoustic wave resonator according to claim 1.

5. The acoustic wave filter according to claim 4, wherein
the first reflection electrode and the third reflection electrode are connected to each other;
the second reflection electrode and the fourth reflection electrode are connected to each other;
the second busbar electrode is connected to the first reflection electrode, the second reflection electrode, the third reflection electrode, and the fourth reflection electrode;
a second electrode finger located outermost in the first direction among the plurality of first electrode fingers and the plurality of second electrode fingers is connected to the first reflection electrode and the second reflection electrode; and
a third electrode finger located outermost in the second direction among the plurality of third electrode fingers and the plurality of fourth electrode fingers is connected to the third reflection electrode and the fourth reflection electrode.

6. The acoustic wave filter according to claim 4, wherein
the first reflection electrode and the third reflection electrode are connected to each other;
the second reflection electrode and the fourth reflection electrode are connected to each other;
the first busbar electrode is connected to the first reflection electrode;
the third busbar electrode is connected to the fourth reflection electrode;
a first electrode finger located outermost in the first direction among the plurality of first electrode fingers and the plurality of second electrode fingers is connected to the first reflection electrode; and
a fourth electrode finger located outermost in the second direction among the plurality of third electrode fingers and the plurality of fourth electrode fingers is connected to the fourth reflection electrode.

7. The acoustic wave filter according to claim 4, further comprising:
a first input/output terminal and a second input/output terminal; and
a ground terminal; wherein
the acoustic wave resonator is directly connected to at least one of the first input/output terminal, the second input/output terminal, and the ground terminal.

8. The acoustic wave resonator according to claim 1, wherein
the first busbar electrode is connected to the first reflection electrode and the second reflection electrode;
the third busbar electrode is connected to the third reflection electrode and the fourth reflection electrode;
a first electrode finger located outermost in the first direction among the plurality of first electrode fingers and the plurality of second electrode fingers is connected to the first reflection electrode and the second reflection electrode; and
a fourth electrode finger located outermost in the second direction among the plurality of third electrode fingers and the plurality of fourth electrode fingers is connected to the third reflection electrode and the fourth reflection electrode.

9. An acoustic wave filter comprising the acoustic wave resonator according to claim 8.

10. The acoustic wave filter according to claim 9, further comprising:
a first input/output terminal and a second input/output terminal;
one or more series arm resonators arranged in series in a path connecting the first input/output terminal and the second input/output terminal; and
one or more parallel arm resonators connected between the path and a ground; wherein
at least one of the one or more series arm resonators includes the acoustic wave resonator.

11. The acoustic wave filter according to claim 10, wherein the acoustic wave resonator is directly connected to at least one of the first input/output terminal and the second input/output terminal.

12. The acoustic wave filter according to claim 9, further comprising:
a first input/output terminal and a second input/output terminal;
one or more series arm resonators arranged in series in a path connecting the first input/output terminal and the second input/output terminal; and
one or more parallel arm resonators connected between the path and a ground; wherein
at least one of the one or more parallel arm resonators includes the acoustic wave resonator.

13. The acoustic wave filter according to claim 12, further comprising:
a ground terminal; wherein
the acoustic wave resonator is directly connected to at least one of the first input/output terminal, the second input/output terminal, and the ground terminal.

14. The acoustic wave filter according to claim 9, further comprising:
a first input/output terminal and a second input/output terminal;
one or more series arm resonators arranged in series in a path connecting the first input/output terminal and the second input/output terminal; and
one or more parallel arm resonators connected between the path and a ground; wherein
a first series arm resonator among the one or more series arm resonators and a first parallel arm resonator among the one or more parallel arm resonators each include the acoustic wave resonator; and
an average gap of a gap between the first reflection electrode and the third reflection electrode and a gap between the second reflection electrode and the fourth reflection electrode of the first series arm resonator is larger than an average gap of a gap between the first reflection electrode and the third reflection electrode and a gap between the second reflection electrode and the fourth reflection electrode of the first parallel arm resonator.

15. The acoustic wave filter according to claim 9, further comprising:
a first input/output terminal and a second input/output terminal;
one or more series arm resonators arranged in series in a path connecting the first input/output terminal and the second input/output terminal; and
one or more parallel arm resonators connected between the path and a ground; wherein
a first series arm resonator among the one or more series arm resonators and a first parallel arm resonator among the one or more parallel arm resonators each include the acoustic wave resonator; and
an average gap of a gap between the first reflection electrode and the third reflection electrode and a gap between the second reflection electrode and the fourth reflection electrode of the first series arm resonator is smaller than an average gap of a gap between the first reflection electrode and the third reflection electrode and a gap between the second reflection electrode and the fourth reflection electrode of the first parallel arm resonator.

16. A multiplexer comprising:
a common terminal;
the acoustic wave filter according to claim 4 connected to the common terminal; and
a first filter connected to the common terminal.

17. The multiplexer according to claim 16, wherein
the first reflection electrode and the third reflection electrode are connected to each other;
the second reflection electrode and the fourth reflection electrode are connected to each other;
the second busbar electrode is connected to the first reflection electrode, the second reflection electrode, the third reflection electrode, and the fourth reflection electrode;
a second electrode finger located outermost in the first direction among the plurality of first electrode fingers and the plurality of second electrode fingers is connected to the first reflection electrode and the second reflection electrode; and
a third electrode finger located outermost in the second direction among the plurality of third electrode fingers and the plurality of fourth electrode fingers is connected to the third reflection electrode and the fourth reflection electrode.

18. The multiplexer according to claim 16, wherein
the first reflection electrode and the third reflection electrode are connected to each other;
the second reflection electrode and the fourth reflection electrode are connected to each other;
the first busbar electrode is connected to the first reflection electrode;
the third busbar electrode is connected to the fourth reflection electrode;
a first electrode finger located outermost in the first direction among the plurality of first electrode fingers and the plurality of second electrode fingers is connected to the first reflection electrode; and
a fourth electrode finger located outermost in the second direction among the plurality of third electrode fingers and the plurality of fourth electrode fingers is connected to the fourth reflection electrode.

19. The multiplexer according to claim 17, further comprising:
a first input/output terminal and a second input/output terminal; and
a ground terminal; wherein
the acoustic wave resonator is directly connected to at least one of the first input/output terminal, the second input/output terminal, and the ground terminal.

20. A multiplexer comprising:
a common terminal;
the acoustic wave filter according to claim 9 connected to the common terminal; and
a filter connected to the common terminal.
